(19) United States
(12) Patent Application Publication
(10) Pub. No.: US 2019/0086586 A1
(43) Pub. Date: Mar. 21, 2019

(54) MICROSTRUCTURE SUBSTRATES, MANUFACTURING METHODS, AND DISPLAY DEVICES

(71) Applicant: Wuhan China Star Opoelectronics Technology Co., Ltd., Wuhan, Hubei (CN)

(72) Inventor: Yong YANG, Shenzhen, Guangdong (CN)

(73) Assignee: Wuhan China Star Optoelectronics Technology Co., L td., Wuhan, Hubei (CN)

(21) Appl. No.: 15/536,079

(22) PCT Filed: May 19, 2017
(86) PCT No.: PCT/CN2017/085087

§ 371 Date: Jun. 14, 2017

(30) Foreign Application Priority Data
Apr. 24, 2017 (CN) 201710271727.7

(51) Int. Cl. G02B 5/02; G02B 1/18; C23C 14/10; C23C 14/58

(52) U.S. Cl. CPC G02B 5/0221; G02B 1/18; C23C 14/5873; C23C 14/10; G02B 5/0268

(57) ABSTRACT

The present disclosure relates to a microstructure substrate and the manufacturing method thereof, and a display device. The method includes coating an anti-fingerprint layer on a substrate, sputtering a SiO2 layer on the anti-fingerprint layer, and etching the SiO2 layer to form the SiO2 layer having a plurality of circular recessed microstructures. With such configuration, the impact caused by the circular depression microstructure to the high-resolution panel may be enhanced so as to reduce the degree of the blur with respect to the images. As such, the substrate may be adopted by high-resolution panels.

### BACKGROUND OF THE INVENTION

### 1. Field of the Invention

The present disclosure relates to display technology, and more particularly to a microstructure substrate, the manufacturing method thereof, and a display device.

### 2. Discussion of the Related Art

Currently, anti-glare methods are usually adopted to manufacture rugged surfaces of glasses or plastic substrates. However, such anti-glare substrate, after being bonded with high-resolution substrate, may have blunt quality, which lowers down the resolution of the panel. Thus, such solution is generally adopted by panel with low resolution requirement.

### SUMMARY

The present disclosure relates to a microstructure substrate and the manufacturing method thereof, and a display device for reducing the impact toward the high-resolution panel caused by the microstructure. This not only may reduce the degree of the blur, but also contribute to the adoption of such substrate.

In one aspect, a display device includes: a microstructure substrate includes: a substrate; an anti-fingerprint layer coated on the substrate; a SiO2 layer covering the anti-fingerprint layer, and the SiO2 layer comprising a plurality of circular depression microstructures; wherein the anti-fingerprint layer is made by mixed solution of SiO2, water-soluble resin, wax and related additive; and a width of the circular depression microstructure is in a range from 5 μm to 25 μm, a ratio of a depth to the width is in the range from 0.05 to 0.15, and an included angle between a tangent of an arc-surface and a horizontal direction is in the range from 5 to 20 degrees.

In another aspect, a manufacturing method of microstructure substrates includes: coating an anti-fingerprint layer on a substrate; sputtering a SiO2 layer on the anti-fingerprint layer; etching the SiO2 layer to form the SiO2 layer having a plurality of circular recessed microstructures.

In another aspect, a microstructure substrate includes: a substrate; an anti-fingerprint layer coated on the substrate; a SiO2 layer covering the anti-fingerprint layer, and the SiO2 layer comprising a plurality of circular depression microstructures.

In view of the above, the anti-glare microstructures are formed on the substrate by applying etching process. In this way, the impact toward the high-resolution panel caused by the microstructure may be reduced. In addition, the degree of the blur with respect to the images may also be reduced.

### BRIEF DESCRIPTION OF THE DRAWINGS

FIG. 1 is a flowchart of the manufacturing method of the microstructure substrates in accordance with one embodiment of the present disclosure.

FIG. 2 is a schematic view of the microstructure substrate in accordance with one embodiment of the present disclosure.

FIG. 3 is a schematic view showing the sputtering direction of the SiO2 and the substrate in accordance with one embodiment of the present disclosure.

FIG. 4 is a schematic view showing the included angle formed by the tangent of the microstructure and the horizontal direction in accordance with one embodiment of the present disclosure.

FIG. 5 is a schematic view of the microstructure in accordance with one embodiment of the present disclosure.

FIG. 6 is a simulation diagram of the microstructure substrate in accordance with one embodiment of the present disclosure.

FIG. 7 is a schematic view of the display device in accordance with one embodiment of the present disclosure.

### DETAILED DESCRIPTION OF THE EMBODIMENTS

Embodiments of the invention will now be described more fully hereinafter with reference to the accompanying drawings, in which embodiments of the invention are shown.

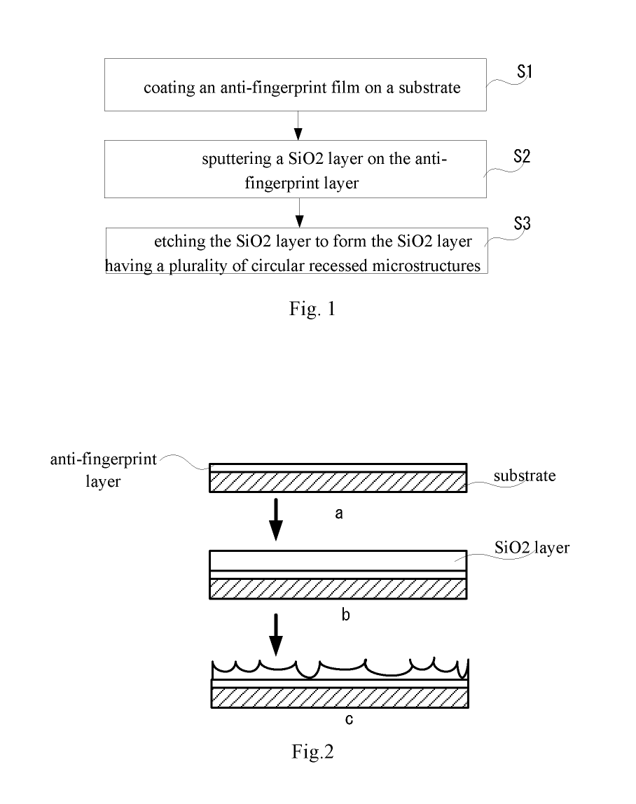

FIG. 1 is a flowchart of the manufacturing method of the microstructure substrates in accordance with one embodiment of the present disclosure. FIG. 2 is a schematic view of the microstructure substrate in accordance with one embodiment of the present disclosure. The method includes the following steps.

In step S1, coating an anti-fingerprint layer on a substrate.

Referring to FIG. 2(a), the substrate may be made by transparent materials, including, but not limited to, glasses, ceramic substrates, transparent plastic, and the like. The substrate has to be cleaned before being processed.

In an example, the anti-fingerprint layer is a mixed solution of SiO2, a water-soluble resin, wax and related additive. The mixed solution mainly includes water-soluble resin organic material. The resistant fingerprint layer has good acid resistance and can prevent the erosion of the etchant. Thus, the microstructure of the subsequent etch process does not have an excessively high aspect ratio (described later). Wherein the SiO2 in the anti-fingerprint layer enhances the adhesion between the anti-fingerprint resistant film and the substrate, improves the adhesion and scratch resistance of the film layer, and the auxiliary agent mainly serves to disperse the mixed solution such that the organic components and inorganic components are in micron, or even nanoscale, dispersion state. Also, the mixed liquid storage and stability, are ensured. The water-soluble resin relates to the bonding-skeleton material for the film. The wax is provided with self-lubricating function so as to improve the processing performance of mixed solution.

In step S2, sputtering a SiO2 layer on the anti-fingerprint layer.

Referring to FIG. 2(b), a thickness of the SiO2 layer sputtered on the anti-fingerprint layer may be in a range from 1 to 3 μm. In other embodiments, the SiO2 layer may be configured on the anti-fingerprint layer, which is not limited to the above.

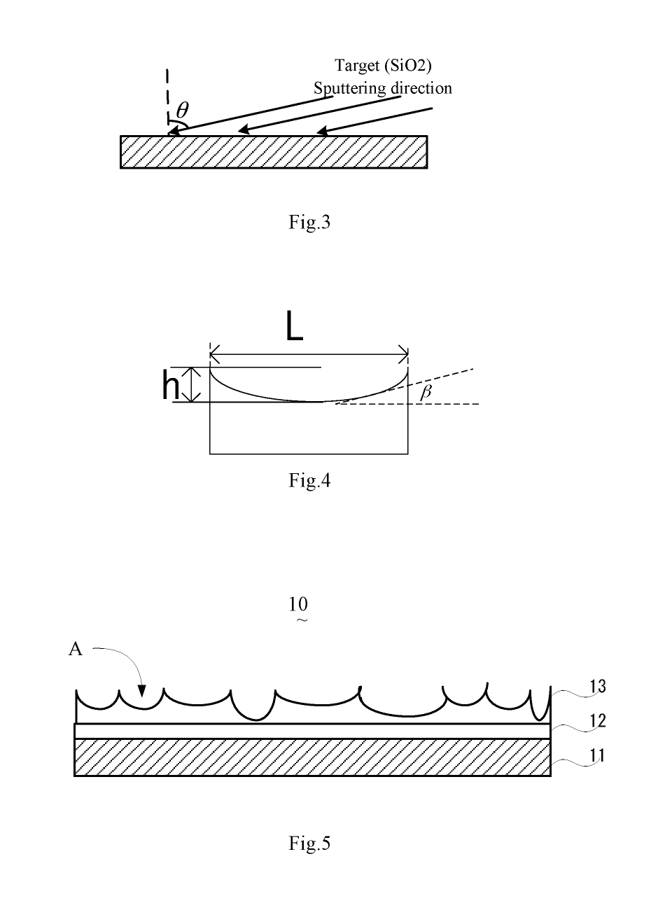

During the sputtering process, the sputtering direction relating to the SiO2 and the substrate has to be adjusted. In an example, the included angle (θ) formed by the sputtering direction and a normal line of the substrate is in a range from 75 to 85 degrees such that the sputtering layer is the SiO2 layer having a large pore density. The etching rate is faster in the subsequent etching process, and the preparation efficiency is improved. FIG. 3 is a schematic view showing the sputtering direction of the SiO2 and the substrate in accordance with one embodiment of the present disclosure.

In step S3, etching the SiO2 layer to form the SiO2 layer having a plurality of circular recessed microstructures.

Referring to FIG. 2(c), after the SiO2 layer is sputtered, the SiO2 layer has to be etched. In an example, a wet etching process is adopted. Nevertheless, it can be understood that other techniques, such as dry etching, may be adopted. The etching solution may be hydrofluoric acid-based mixed acid solution. In other embodiments, other etching solutions capable of eroding the silicon dioxide layer may be adopted.

In the etching process, it is necessary to control the corresponding etching parameters to ensure that the desired microstructure is obtained. The corresponding etching parameters include at least one of the etching solution concentration, the etching time period, and the etching fluid flow rate. The etching conditions are controlled to obtain a SiO2 layer having a plurality of circular recessed microstructures, wherein a width (L) of the circular depression microstructure may be 5 μm to 25 μm, a ratio of the depth (h) to the width (L) may be 0.05 to 0.15, and the included angle (β) between the tangent of the arc-surface and the horizontal direction is 5 to 20 degrees (refer to FIG. 4).

In view of the above, the shape of the microstructure and the related parameters of the substrate having the circular depression microstructure may be controlled. In this way, the impact toward the high-resolution panel caused by the microstructure may be reduced. In addition, the degree of the blur with respect to the images may also be reduced.

In view of the above, the anti-glare circular depression microstructures are formed on the substrate by applying etching processes. The impact caused by the circular depression microstructure to the high-resolution panel may be enhanced so as to reduce the degree of the blur with respect to the images. As such, the substrate may be adopted by high-resolution panels.

FIG. 5 is a schematic view of the microstructure in accordance with one embodiment of the present disclosure. The microstructure substrate 10 includes a substrate 11, an anti-fingerprint layer 12, and a SiO2 layer 13.

The substrate 11 may be made by transparent materials, including, but not limited to, glasses, ceramic substrates, transparent plastic, and the like.

The anti-fingerprint layer 12 is coated on the substrate 11. The anti-fingerprint layer 12 is a mixed solution of SiO2, water-soluble resin, wax and related additive, wherein the mixed solution mainly includes water-soluble resin organic material.

The SiO2 layer 13 covers the anti-fingerprint layer 12, and the SiO2 layer 13 includes a plurality of circular depression microstructures (A), wherein a width (L) of the circular depression microstructure may be 5 μm to 25 μm, a ratio of the depth (h) to the width (L) may be 0.05 to 0.15, and the included angle (β) between the tangent of the arc-surface and the horizontal direction is 5 to 20 degrees.

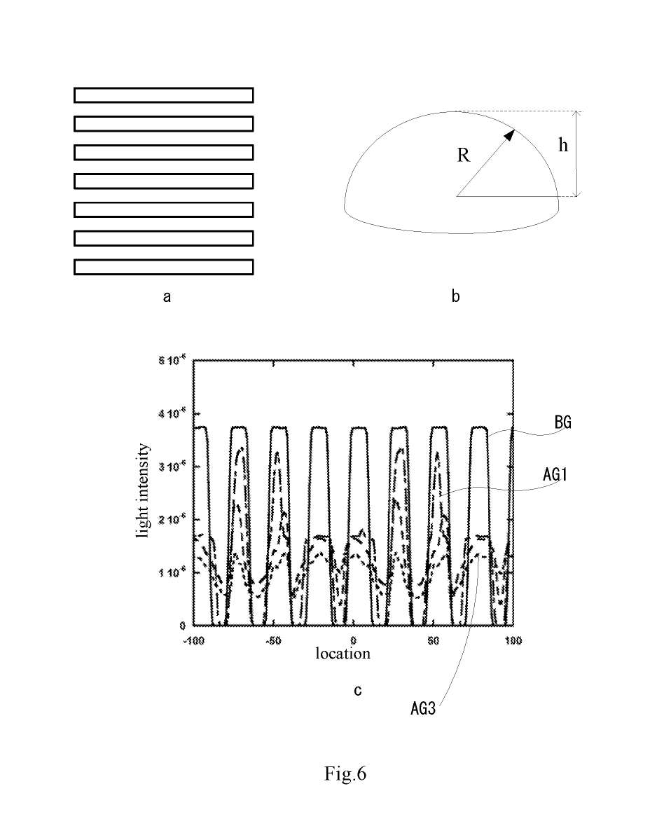

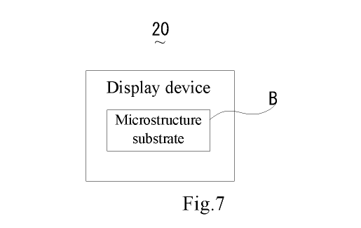

FIG. 6 is a simulation diagram of the microstructure substrate in accordance with one embodiment of the present disclosure. FIG. 6(a) shows a testing picture, i.e., the standard sine grating picture. FIG. 6(b) shows the structure of the substrate having the circular depression microstructures. FIG. 6(c) shows the light intensity obtained by simulating the morphology of the microstructure using three different heights (h) and widths (L).

The width (L) of the microstructure (AG1, AG2, and AG3) are 20 μm, and the ratios of the height to the width (“height-to-width-ratio”) with respect to the substrate without the microstructure are respectively 0.1, 0.2, 0.3. In view of the simulation, when the height-to-width-ratio is smaller, the quality of reproduction is better. Along with the increase of the height-to-width-ratio, the sharpness and the contrast of the images greatly drop, and the degree of blur increases greatly. That is, the smaller height-to-width-ratio contributes to the resolution of the images. Further combining with the anti-glare effect of the microstructure, it is obtained that the overall performance is better when the height-to-width-ratio of the circular depression microstructure is within a range from 0.05 to 0.15.

FIG. 7 is a schematic view of the display device in accordance with one embodiment of the present disclosure. The display device 20 includes a substrate (B) having the above microstructure, or the substrate manufactured by the above method.

In view of the above, the anti-glare microstructures are formed on the substrate by applying etching process. In this way, the impact toward the high-resolution panel caused by the microstructure may be reduced. In addition, the degree of the blur with respect to the images may also be reduced.

It is believed that the present embodiments and their advantages will be understood from the foregoing description, and it will be apparent that various changes may be made thereto without departing from the spirit and scope of the invention or sacrificing all of its material advantages, the examples hereinbefore described merely being preferred or exemplary embodiments of the invention.

What is claimed is:

1. A display device, comprising:
a microstructure substrate comprising:
a substrate;
an anti-fingerprint layer coated on the substrate;
a SiO2 layer covering the anti-fingerprint layer, and the SiO2 layer comprising a plurality of circular depression microstructures;
wherein the anti-fingerprint layer is made by mixed solution of SiO2, water-soluble resin, wax and related additive;
and a width of the circular depression microstructure is in a range from 5 μm to 25 μm, a ratio of a depth to the width is in the range from 0.05 to 0.15, and an included angle between a tangent of an arc-surface and a horizontal direction is in the range from 5 to 20 degrees.

2. A manufacturing method of microstructure substrates, comprising:
coating an anti-fingerprint layer on a substrate;
sputtering a SiO2 layer on the anti-fingerprint layer;
etching the SiO2 layer to form the SiO2 layer having a plurality of circular recessed microstructures.

3. The manufacturing method as claimed in claim 1, wherein the step of sputtering the SiO2 layer on the anti-fingerprint layer further comprises:
adjusting a sputtering direction relating to the SiO2 layer and the substrate, wherein the included angle formed by the sputtering direction and a normal line of the substrate is in a range from 75 to 85 degrees.

4. The manufacturing method as claimed in claim 3, wherein a thickness of the SiO2 layer is in a range from 1 to 3 μm.

5. The manufacturing method as claimed in claim 2, wherein the step of applying the etching process to the SiO2 layer comprises:
controlling corresponding etching parameters, wherein the etching parameters comprises at least one of an etching solution concentration, an etching time period, and an etching fluid flow rate.

6. The manufacturing method as claimed in claim 2, wherein a width of the circular depression microstructure is in a range from 5 μm to 25 μm.

7. The manufacturing method as claimed in claim 2, wherein a ratio of a depth to the width is in the range from 0.05 to 0.15.

8. The manufacturing method as claimed in claim 2, wherein an included angle between a tangent of an arc-surface and a horizontal direction is in the range from 5 to 20 degrees.

9. The manufacturing method as claimed in claim 2, wherein the anti-fingerprint layer is made by mixed solution of SiO2, water-soluble resin, wax and related additive;

10. A microstructure substrate, comprising:
a substrate;
an anti-fingerprint layer coated on the substrate;
a SiO2 layer covering the anti-fingerprint layer, and the SiO2 layer comprising a plurality of circular depression microstructures.
